(19) United States
(12) Patent Application Publication
(10) Pub. No.: US 2018/0053737 A1
(43) Pub. Date: Feb. 22, 2018

(54) POWER SEMICONDUCTOR DEVICE

(71) Applicant: MITSUBISHI ELECTRIC CORPORATION, Chiyoda-ku, Tokyo (JP)

(72) Inventors: Shohei OGAWA, Chiyoda-ku, Tokyo (JP); Masao KIKUCHI, Chiyoda-ku, Tokyo (JP); Junji FUJINO, Chiyoda-ku, Tokyo (JP); Yoshihisa UCHIDA, Chiyoda-ku, Tokyo (JP); Yuichiro SUZUKI, Chiyoda-ku, Tokyo (JP); Tatsunori YANAGIMOTO, Chiyoda-ku, Tokyo (JP)

(73) Assignee: MITSUBISHI ELECTRIC CORPORATION, Chiyoda-ku, Tokyo (JP)

(21) Appl. No.: 15/557,046

(22) PCT Filed: Feb. 26, 2016
(86) PCT No.: PCT/JP2016/055803

§ 371 Date: Sep. 8, 2017

(30) Foreign Application Priority Data
Mar. 10, 2015 (JP) 2015-046846

(51) Int. Cl. H01L 23/00

(52) U.S. Cl. CPC H01L 24/05; H01L 24/48; H01L 24/03; H01L 24/49; H01L 2224/04042; H01L 2224/03464; H01L 2224/05083; H01L 2224/05082; H01L 2224/05147; H01L 2224/05155; H01L 2224/05124; H01L 2224/05084; H01L 2224/05144; H01L 2224/05164; H01L 2924/07025; H01L 2224/05005; H01L 2924/2064; H01L 2224/05016; H01L 2224/45147; H01L 2224/05012; H01L 2224/05013; H01L 2224/05015; H01L 2224/05022; H01L 2224/48091; H01L 2224/48106; H01L 2224/48227; H01L 2224/49175; H01L 2224/06131; H01L 24/06; H01L 24/45

(57) ABSTRACT

In a power semiconductor device, a front-surface electrode of a power semiconductor element is formed in such a manner that, on a first Cu layer consisting mainly of Cu, formed by non-electrolytic plating and having a Vickers hardness of 200 to 350 Hv, a second Cu layer consisting mainly of Cu, formed by non-electrolytic plating and having a Vickers hardness of 70 to 150 Hv and thus being softer than the first Cu layer, is laminated. The second Cu layer and a wire made of Cu are wire-bonded together.

### TECHNICAL FIELD

The present invention relates to a power semiconductor device to which a bonding wire is connected for electrical wiring between a front-surface electrode of a power semiconductor element and an external electrode.

### BACKGROUND ART

Heretofore, Al-wire bonding has been practiced for electrical wiring of a power semiconductor device; however, in response to a demand for increased operation temperature and increased reliability, there is a need to reconsider the material of the wire. Thus, bonding with Cu wire that is large in electrical capacity and high in mechanical strength and is thus expected to have improved reliability, is under development. However, when bonding is performed using a Cu wire by wedge bonding similar to in the case of using a conventional Al wire, because Cu has a Young modulus that is higher when compared with Al, there is a concern of causing damage to a semiconductor element at the time of bonding. Such a structure is required that allows a Cu wire to be bonded to the semiconductor element without causing damage thereto.

In Patent Document 1, an invention is disclosed in which a Ni/Pd/Au film is formed on an electrode of the power semiconductor element to thereby prevent occurrence of damage to the power semiconductor element at the time of wire bonding. Further, in Patent Document 2, an invention is disclosed in which a highly-hard protective film of W, Co, Mo, Ti and/or Ta is formed on the element, and then, on that film, a Cu film is formed, to thereby establish both a bonding capability and a damage reducing effect.

### CITATION LIST

### Patent Document

Patent Document 1: Japanese Patent Application Laid-open No. 2013-004781 (Paragraph 0019; FIG. 2)

Patent Document 2: Japanese Patent Application Laid-open No. 2014-082367 (Paragraph 0020; FIG. 1)

### SUMMARY OF THE INVENTION

### Problems to be Solved by the Invention

However, in Patent Document 1, although the film is formed as (non-electrolytically plated Ni)/Pd/Au, because the plated Ni has a large film stress, there is a problem that a warpage or peeling occurs in the film when its thickness is increased, in order to fully exert the damage reducing effect for the element with a large area to be used in a power semiconductor device. Further, because of the large film stress, there is a problem that the plated Ni film is cracked by a stress at the time of bonding.

Meanwhile, in Patent Document 2, in order not to bring damage in the power semiconductor element at the time of wire bonding, the film of W or the like, is formed on the electrode of the power semiconductor element, so as to function as a buffer material. However, other than the use of sputtering, there is no way to form the metal film of W or the like, so that there is a problem that, when the film thickness is increased in order to increase the damage reducing effect, this will result in reduced productivity. Furthermore, when a Cu wire is bonded to such a film structure, there is a problem that, under the influence of thermal stress due to difference in their linear expansion coefficients, a crack occurs in the Cu wire or a peeling occurs in the metal film.

The present invention has been made to solve the problems as described above, and an object thereof is to provide a power semiconductor device which can reduce damage to the semiconductor element when bonding is performed using a Cu wire.

### Means for Solving the Problems

A power semiconductor device according to the invention is characterized by comprising: a power semiconductor element; a first electrode layer formed on the power semiconductor element; a second electrode layer formed on the first electrode layer, said second electrode layer consisting mainly of Cu and having a hardness lower than that of the first electrode layer; and a bonding wire consisting mainly of Cu and connected to the second electrode layer.

### Effect of the Invention

According to the invention, because a layer that is low in hardness and superior in bonding capability is formed as an outermost-surface electrode layer, even when bonding using a Cu wire is applied to the power semiconductor element, it is possible to bond the wire to the power semiconductor element with reduced damage thereto, to thereby achieve wiring with superior reliability. Further, it is possible to suppress peeling or crack from occurring in the front-surface electrode, to thereby improve the productivity.

### BRIEF DESCRIPTION OF THE DRAWINGS

FIG. 1 is a schematic cross-sectional view showing a configuration of a power semiconductor device according to Embodiment 1 of the invention.

FIG. 2 is an enlarged cross-sectional view showing a configuration of a main part of the power semiconductor device according to Embodiment 1 of the invention.

FIG. 3 is an enlarged cross-sectional view showing a configuration of a main part of a power semiconductor device according to Embodiment 2 of the invention.

FIG. 4 is an enlarged cross-sectional view showing a configuration of a main part of a power semiconductor device according to Embodiment 3 of the invention.

FIG. 5 is an enlarged perspective view showing a configuration of a main part of a power semiconductor device according to Embodiment 4 of the invention.

FIG. 6 is an enlarged cross-sectional view showing a configuration of a main part of the power semiconductor device according to Embodiment 4 of the invention.

FIG. 7A, FIG. 7B, FIG. 7C and FIG. 7D are enlarged top views each showing another configuration of a main part of the power semiconductor device according to Embodiment 4 of the invention.

FIG. 8A, FIG. 8B, FIG. 8C and FIG. 8D are enlarged cross-sectional views each showing another configuration of a main part of the power semiconductor device according to Embodiment 4 of the invention.

FIG. 9 is an enlarged cross-sectional view showing a configuration of a main part of the power semiconductor device according to Embodiment 5 of the invention.

### MODES FOR CARRYING OUT THE INVENTION

### Embodiment 1

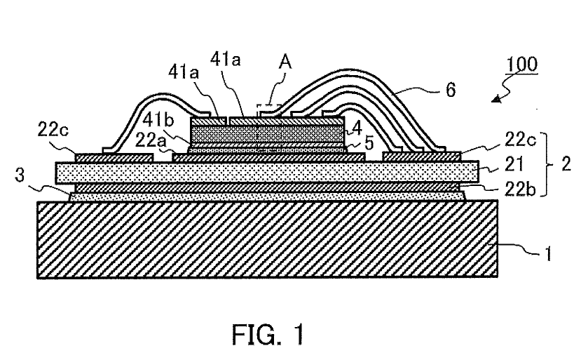

A power semiconductor device corresponding to Embodiment 1 of the invention will be described with reference to the drawings, as follows. FIG. 1 is a schematic cross-sectional view showing a configuration of the power semiconductor device according to Embodiment 1 of the invention.

As shown in FIG. 1, a power semiconductor device 100 is configured with: a base plate 1; a ceramic board 2 bonded onto the base plate 1; a power semiconductor element 4 placed on the ceramic board 2; and wires 6 for bonding between a front-surface electrode 41a of the power semiconductor element 4 and an electrode layer 22c formed as a circuit pattern on the ceramic board 2.

The base plate 1 used is a plate made of Cu serving as a heat-dissipation plate. Onto the base plate 1, the ceramic board 2 is bonded using a solder (Sn—Ag—Cu base) 3. The base plate 1 may be of any material having a high heat-transfer coefficient and thus, a plate made of Al or the like, may be used. Further, it may be a base board integrated with an insulating board. As the solder 3, although an Sn—Ag—Cu base solder is used, it is allowable to use an Sn—Ag—Cu—Sb base solder, a Pb-containing solder or the like, so far as it can bond the base plate 1 and the ceramic board 2 together and can ensure heat dissipation capability. Instead, sintering bonding using Ag or other particles, or connection by means of a heat dissipation sheet or a thermal grease, may be applied.

The ceramic board 2 includes a base member 21 made of AlN on both surfaces of which conductive layers 22a, 22b, 22c each made of Cu are laminated. The electrode layer 22b on the back-surface side of the ceramic board 2 is bonded onto the base plate 1 by the solder 3, and the power semiconductor element 4 is placed on the conductive layer 22a on the front-surface side. Further, the electrode layer 22c provided as the circuit pattern on the ceramic board 2 is bonded by means of the wires 6 to the front-surface electrode 41a of the power semiconductor element 4. The base member 21 may be made of Al₂O₃, Si₃N₄ or the like, so far as it can ensure an insulation property.

As the power semiconductor element 4, an IGBT (Insulated Gate Bipolar Transistor) made of Si is used, and its back-surface electrode 41b is die-bonded by an Ag sintered member 5 to the conductive layer 22a on the ceramic board 2. The front-surface electrode 41a is bonded by wedge bonding using the wires 6, to all portions in the electrode layer 22c on the front-surface side, including a main wiring toward a source pad, a gate wiring, wirings toward a variety of sensing pads, which are provided as the circuit pattern on the ceramic board 2. As each of the wires 6, a wire consisting mainly of Cu and having a diameter of φ400 μm is used.

As the power semiconductor element 4, although an IGBT is used, it may be an IC (Integrated Circuit), a thyristor or a MOSEFT (Metal Oxide Semiconductor Field Effect Transistor). It may also be a diode, such as an SBD (Schottky Barrier Diode), a JBS (Junction Barrier Schottky), or the like. Further, it may be applied to a semiconductor package other than that for power semiconductor. Further, although its thickness is given as 100 μm, it is not limited thereto. Ag-sintering is used for die-bonding of the power semiconductor element 4; however, soldering may be used therefor. Further, sintering bonding using a material such as Cu, other than Ag, may be used therefor.

As each of the wires 6, a wire consisting mainly of Cu and having a diameter of 400 μm is used; however, the wires are not limited thereto. Different wire-diameters may be applied to them in such a manner that, among them, the wire 6 for gate wiring and the wires 6 for wirings toward the sensing pads are only made smaller in wire-diameter. Further, as only the wire 6 for gate wiring, the conventional Al wire or Al-alloy wire consisting mainly of Al may be used. Wedge bonding is used for bonding of the wires 6; however, ball bonding or ultrasonic bonding may be used therefor. Further, with respect also to the main wiring toward the source pad, not only the wire 6 consisting mainly of Cu, but also a wire of a pure metal or an alloy consisting mainly of Al or Ag. Furthermore, instead of the wire 6, a ribbon or a lead frame may be bonded ultrasonically.

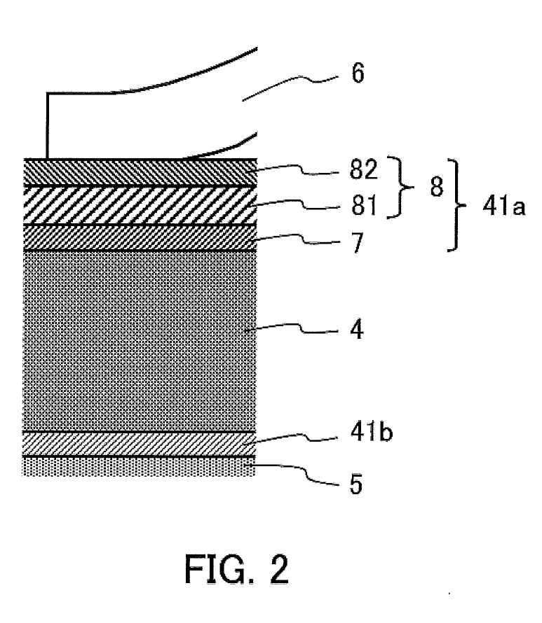

FIG. 2 is a schematic view showing a configuration of a main part of the power semiconductor device 100 according to Embodiment 1 of the invention, which is an enlarged cross-sectional view of a region A in FIG. 1. As shown in FIG. 2, the front-surface electrode 41a of the power semiconductor element 4 is configured with plural metal layers of a Cu layer 8 and an Al layer 7. Further, the Cu layer 8 comprises: a soft Cu layer 82 consisting mainly of Cu, formed by non-electrolytic plating and having a Vickers hardness of 70 to 150 Hv; and a hard Cu layer 81 consisting mainly of Cu, formed by non-electrolytic plating and having a Vickers hardness of 200 to 350 Hv. Namely, the outermost surface of these plural metal layers is provided by the soft Cu layer 82 consisting mainly of Cu, formed by non-electrolytic plating and having a Vickers hardness of 70 to 150 Hv, and under that layer, the hard Cu layer 81 consisting mainly of Cu, formed by non-electrolytic plating and having a Vickers hardness of 200 to 350 Hv is placed. Further, under that layer, the Al layer 7 consisting mainly of Al is formed as a film by sputtering. Their respective film-thicknesses are 0.1 to 5 μm for the Al layer 7, 5 to 20 μm for the Cu layer 81, and 5 to 20 μm for the Cu layer 82. The wire 6 is bonded by wedge bonding to the Cu layer formed to provide the outermost surface of the front-surface electrode 41a.

A difference in their Vickers hardness is reflected in their grain sizes, so that the higher the hardness, the smaller the grain size. The difference in the grain sizes can be controlled by an ion concentration, etc. in a plating solution. The hard Cu layer 81 has an average grain size of 1 μm or less, and the soft Cu layer 82 has an average grain size of 5 μm or more. The grain size can also be controlled by a post-plating heat treatment.

Although the film formation of the Al layer 7 as a plating underlayer is made by sputtering, the plating underlayer is not limited to the Al layer 7, and may be a Cu layer, a Ni layer or the like. Further, the Cu layer and the Cu layer 82 are not limited to non-electrolytically plated layers, and may be formed by electrolytic plating or sputtering. When they are formed by sputtering, the Al layer 7 as a base may be omitted.

The reason why such a configuration is applied will be described below. In Table 1, with respect to a Vickers hardness of each plated Cu, an evaluation result of bonding capability thereof to the wire 6, which was made by the inventors, is shown. Ultrasonic-wave power shown in Table 1 is a value specific to the apparatus (in the table, each given as an arbitrary unit [a.u.]), and it is meant that the lower the bondable ultrasonic-wave power, the smaller the damage caused to the power semiconductor element 4. Further, it is meant that, as the width of bondable power of the ultrasonic wave becomes broader, the margin of the bonding condition becomes broader, so that the yield is expected to be improved. Note that in this experiment, the film thickness is always given as 30 μm.

TABLE 1
Evaluation Result of Bonding Capability

| | | Ultrasonic-Wave Power [a.u.] | | | | | | |
|---|---|---|---|---|---|---|---|---|
| | | 30 | 35 | 40 | 45 | 50 | 55 | 60 |
| Vickers | 70 | ◯ | ◯ | ◯ | ◯ | ◯ | X | X |
| Hardness | 120 | ◯ | ◯ | ◯ | ◯ | ◯ | X | X |
| [Hv] | 150 | ◯ | ◯ | ◯ | ◯ | ◯ | X | X |
| | 160 | — | — | — | ◯ | ◯ | X | X |
| | 200 | — | — | — | — | ◯ | ◯ | ◯ |
| | 250 | — | — | — | — | ◯ | ◯ | ◯ |
| | 350 | — | — | — | — | ◯ | ◯ | ◯ |
| | 450 | — | — | Δ | Δ | Δ | Δ | Δ |

As a result, as shown in Table 1, when the Vickers hardness is from 70 to 150 Hv, the wire 6 is bonded to result in achievement of electrical characteristics (o), even when the ultrasonic-wave power is low power. In contrast, when the Vickers hardness is 160 Hv or more, the wire 6 is difficult to be bonded at low power (−), so that the condition margin becomes smaller. Further, at high power, when the Vickers hardness is 160 Hv or less, the power semiconductor element 4 is broken and as the result, no electrical characteristic is achieved (x). On the other hand, when the Vickers hardness exceeds 200 Hv, the wire 6 is connected to achieve electrical characteristics (∘) and a damage reducing effect is found. However, when the Vickers hardness is 450 Hv or more, a crack (Δ) occurs on the plated surface.

Next, in Table 2 and Table 3, with respect to the thickness of each plated Cu, an evaluation result of bonding capability thereof to the wire 6, which was made by the inventors, is shown; Table 2 shows the result when the Vickers hardness of the plated Cu is 120 Hv, and Table 3 shows the result when the Vickers hardness of the plated Cu is 250 Hv.

TABLE 2
Evaluation Result of Bonding Capability

| | | Ultrasonic-Wave Power [a.u.] | | | | | | |
|---|---|---|---|---|---|---|---|---|
| | | 30 | 35 | 40 | 45 | 50 | 55 | 60 |
| Plated Film | 2 | X | X | X | X | X | X | X |
| Thickness | 5 | X | X | X | X | X | X | X |
| [μm] | 10 | ◯ | X | X | X | X | X | X |
| | 20 | ◯ | ◯ | ◯ | ◯ | X | X | X |
| | 30 | ◯ | ◯ | ◯ | ◯ | ◯ | X | X |

TABLE 3
Evaluation Result of Bonding Capability

| | | Ultrasonic-Wave Power [a.u.] | | | | | | |
|---|---|---|---|---|---|---|---|---|
| | | 30 | 35 | 40 | 45 | 50 | 55 | 60 |
| Plated Film | 2 | — | — | — | — | — | — | — |
| Thickness | 5 | — | — | — | — | — | — | — |
| [μm] | 10 | — | — | — | — | — | — | ◯ |
| | 20 | — | — | — | — | ◯ | ◯ | ◯ |
| | 30 | — | — | — | — | ◯ | ◯ | ◯ |

As a result, in the case of Table 2 where the Vickers hardness of the plated Cu is 120 Hv, when the plated thickness is less than 20 μm, except when the ultrasonic-wave power is 30 [a.u.], this results in that the power semiconductor 4 is broken and thus no electrical characteristic is achieved (x). When the plated thickness is 20 μm or more, the wire 6 is connected to achieve electrical characteristics (∘) and a damage reducing effect is found. However, at high power, the power semiconductor element 4 is broken and thus no electrical characteristic is achieved (x).

On the other hand, in the case of Table 3 where the Vickers hardness of the plated Cu is 250 Hv, when the film thickness is 5 μm or less, the wire 6 can not be bonded (−), and even when the film thickness is 10 μm or more, at low power, the wire 6 can not be bonded (−); however, in either of these instances, the power semiconductor element 4 is not broken. At high power, the wire 6 is connected to achieve electrical characteristics (∘).

From the above results, it is thought that, when these plating are combined, namely, when the Cu layer 82 consisting mainly of Cu and formed by non-electrolytic plating, which is relatively soft and thus bondable at low ultrasonic-wave power, and the Cu layer 81 consisting mainly of Cu and formed by non-electrolytic plating, which is relatively hard and through which the power semiconductor element 4 is hardly to be broken, are laminated together, the wire 6 can be wedge-bonded to the power semiconductor element 4 without causing damage thereto. Further, when they are combined, the entire thickness of the Cu layer 8 can be thinner to thereby provide such plating that is superior in productivity. If fabrication variation and mass productivity are considered, with respect to the Vickers hardness, it is preferable when the Cu layer 82 formed by non-electrolytic plating is in a range of 70 to 150 Hv; the hardness of less than 70 Hv is a lower limit of the hardness of Cu, and when the hardness exceeds 150 Hv, the wire 6 is difficult to be bonded at low power. In contrast, it is preferable when the Cu layer 81 formed by non-electrolytic plating is in a range of 200 to 350 Hv; when the hardness is less than 200 Hv, at high power, the power semiconductor element 4 is broken and thus no electrical characteristic is achieved, and when it exceeds 350 Hv, a crack is likely to occur in the Cu layer 81. Further, with respect the film thickness, it is preferable when the Cu layer 82 is in a range of 5 to 20 μm; when the thickness is less than 5 μm, the power semiconductor element 4 is broken and thus no electrical characteristic is achieved, and when it exceeds 20 μm, this results in reduced productivity. It is also preferable when the Cu layer 81 is in a range of 5 to 20 μm; when the thickness is less than 5 μm, the power semiconductor element 4 is broken and thus no electrical characteristic is achieved, and when it exceeds 20 μm, this results in reduced productivity.

Further, when this configuration is applied, because the bonding portion between the front-surface electrode 41a of the power semiconductor element 4 and the wire 6 is provided by Cu to Cu bonding, there is a merit in that: it is possible to reduce their inconsistency in linear expansion coefficient; in addition, Kirkendall void due to diffusion is not formed because of the same type of metal. Moreover, in comparison to Al, Cu is a metal that is higher in Young modulus, smaller in linear expansion coefficient and thus closer to the power semiconductor element, and is high in strength and thus less likely to be plastically deformed. This creates an effect that the Cu layer 8 is suppressed from peeling even when a thermal strain is produced due to a temperature cycle, to thereby achieve wiring with superior reliability. Further, because the processing is completed only by non-electrolytic plating, it is easier to increase the film thickness than by sputtering.

It is noted that the film thickness of the soft Cu layer 82 formed by non-electrolytic plating may be increased to the extent that this layer can reduce the damage to the power semiconductor element 4, to thereby establish a structure without the hard Cu layer 81 formed by non-electrolytic plating. In this case, the Cu layer 82 formed by non-electrolytic plating is a film consisting mainly of Cu, and is thus easily oxidized. When the oxidized film becomes thick, there is a concern of causing a harmful effect to the bonding capability of the wire 6. Thus, between the film formation process of the Cu layer 82 and the bonding process of the Cu wire 6, a process of forming an anti-oxidation film by use of an organic solvent is added. This makes it possible to reduce the influence by such storage to the wire-bonding capability.

The Vickers hardness according to non-electrolytic plating is adjustable by changing the additive in the plating solution or the processing temperature. Further, other than by measuring the Vickers hardness, it is possible to easily recognize that the different layers are formed, by observing their cross-sections because their grain sizes are different to each other.

As described above, in accordance with the power semiconductor device 100 according to Embodiment 1 of the invention, in the front-surface electrode 41a of the power semiconductor element 4, there are provided: as a first electrode layer, the Al layer 7 and the Cu layer 81 which is placed thereon, consisting mainly of Cu, formed by non-electrolytic plating, and having a Vickers hardness of 200 to 350 Hv; and as a second electrode layer, the Cu layer 82 which is provided in a laminated manner on that Cu layer, consisting mainly of Cu, formed by non-electrolytic plating and having a Vickers hardness of 70 to 150 Hv and thus being more soft than the Cu layer 81, wherein the Cu layer 82 and the wire 6 made of Cu are wire-bonded together. Thus, even when bonding using a Cu wire is applied to the power semiconductor element, it is possible to bond the wire to the power semiconductor element with reduced damage thereto, to thereby achieve wiring with superior reliability. Further, it is possible to suppress peeling or crack from occurring in the front-surface electrode, to thereby improve the productivity.

### Embodiment 2

In Embodiment 1, such a configuration is applied in which, in the front-surface electrode 41a of the power semiconductor element 4, on the Cu layer 81 formed by non-electrolytic plating, the Cu layer 82 formed by non-electrolytic plating and being more soft than the Cu layer 81 is laminated, whereas in Embodiment 2, such a case will be described in which, between the Cu layer 81 and the Cu layer 82, a metal layer for improving their adhesion strength is provided.

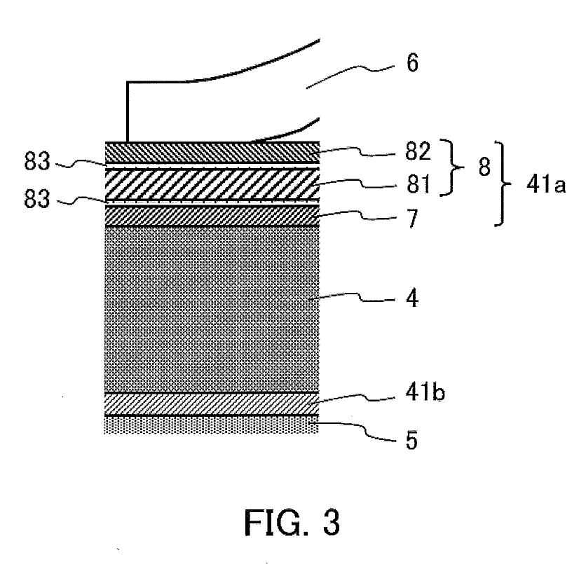

FIG. 3 is an enlarged cross-sectional view showing a configuration of a main part of a power semiconductor device according to Embodiment 2 of the invention. As shown in FIG. 3, in the front-surface electrode 41a of the power semiconductor element 4, both or either in between the Cu layer 81 formed by non-electrolytic plating and the Cu layer 82 formed by non-electrolytic plating and being more soft than the Cu layer 81 and/or in between the Cu layer 81 formed by non-electrolytic plating and the Al layer 7, a metal layer 83 composed of Au is formed as a film for improving their adhesion strength. Note that Au is not limitative, and Pd or the like may be used instead so far as it can increase the adhesion strength. The other configuration is similar to in the power semiconductor device 100 of Embodiment 1, so that its description is omitted here.

It is noted that, though depending on a combination of these metal films, there is a concern of forming a metallic compound layer, so that an anti-diffusion film composed of Ni or the like, may be formed additionally. Further, in order to make easier the film-formation of the Cu layer 81 and the Cu layer 82 by non-electrolytic plating, a seed layer of 0.1 μm or less, consisting mainly of Cu, may be formed beforehand as a film under each of these layers.

As described above, in accordance with the power semiconductor device according to Embodiment 2 of the invention, in the front-surface electrode 41a of the power semiconductor element 4, both or either in between the Cu layer 81 and the Cu layer 82 that is more soft than the Cu layer 81 and/or in between the Cu layer 81 and the Al layer 7, the metal layer 83 composed of Au is formed. Thus, even when bonding using a Cu wire is applied to the power semiconductor element, it is possible not only to reduce damage to the power semiconductor element, but also to increase the adhesion strength in the front-surface electrode, so that the productivity can be improved and wiring can be achieved with much superior reliability.

### Embodiment 3

In Embodiment 1, such a configuration is applied in which, in the front-surface electrode 41a of the power semiconductor element 4, on the Cu layer 81 formed by non-electrolytic plating, the Cu layer 82 formed by non-electrolytic plating and being more soft than the Cu layer 81 is laminated, whereas in Embodiment 3, such a case will be described in which a hard Ni layer is placed under the soft Cu layer.

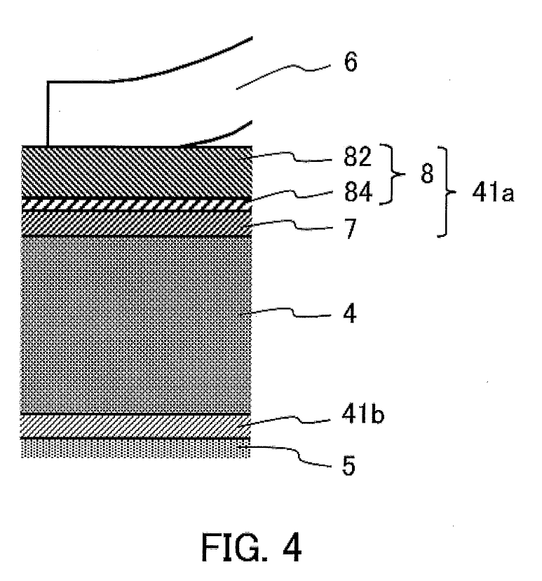

FIG. 4 is an enlarged cross-sectional view showing a configuration of a main part of a power semiconductor device according to Embodiment 3 of the invention. As shown in FIG. 4, in the front-surface electrode 41a of the power semiconductor element 4, under the soft Cu layer 82 consisting mainly of Cu, formed by non-electrolytic plating and having a Vickers hardness of 70 to 150 Hv, there is formed, instead of the Cu layer 81, an Ni layer 84 consisting mainly of Ni, formed by non-electrolytic plating and being more hard than the Cu layer 82. The film thickness of the Ni layer 84 is given as 5 to 20 μm. The other configuration is similar to in the power semiconductor device 100 of Embodiment 1, so that its description is omitted here.

When this configuration is applied, it is possible to reduce damage to the power semiconductor element 4 by the Ni layer 84 formed by non-electrolytic plating, and to ensure the bonding capability by the Cu layer 82 formed by non-electrolytic plating. Further, between the Al layer 7 and the Cu layer 82, Ni is formed as a film, so that it functions as a barrier layer for preventing their diffusion.

It is noted that, also in Embodiment 3, as described in Embodiment 2, both or either in between the Ni layer 84 formed by non-electrolytic plating and the Cu layer 82 formed by non-electrolytic plating, and/or in between the Ni layer 84 and the Al layer 7, the metal layer 83 composed of Au, Pd or the like, for improving their adhesion strength, may be formed as a film of 0.1 μm or less.

As described above, in accordance with the power semiconductor device according to Embodiment 3 of the invention, in the front-surface electrode 41a of the power semiconductor element 4, under the soft Cu layer 82 consisting mainly of Cu, formed by non-electrolytic plating and having a Vickers hardness of 70 to 150 Hv, there is formed the Ni layer 84 consisting mainly of Ni, formed by non-electrolytic plating and being more hard than the Cu layer 82. Thus, even when bonding using a Cu wire is applied to the power semiconductor element, it is possible to bond the wire to the power semiconductor element with reduced damage thereto, to thereby achieve wiring with superior reliability. Further, it is possible to suppress peeling or crack from occurring in the front-surface electrode, to thereby improve the productivity.

### Embodiment 4

In Embodiment 1, such a configuration is applied in which plural wires 6 are bonded to one front-surface electrode 41a, whereas in Embodiment 4, such a case will be described in which front-surface electrodes are provided respectively corresponding to the plural wires 6.

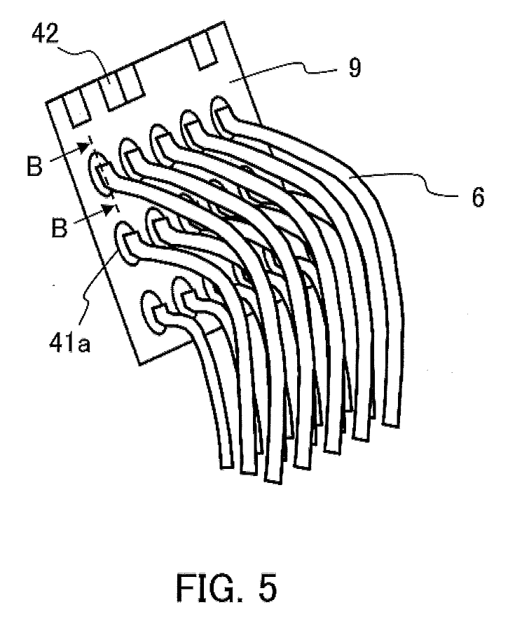

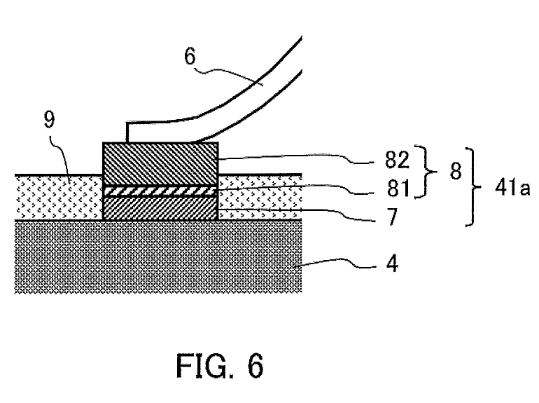

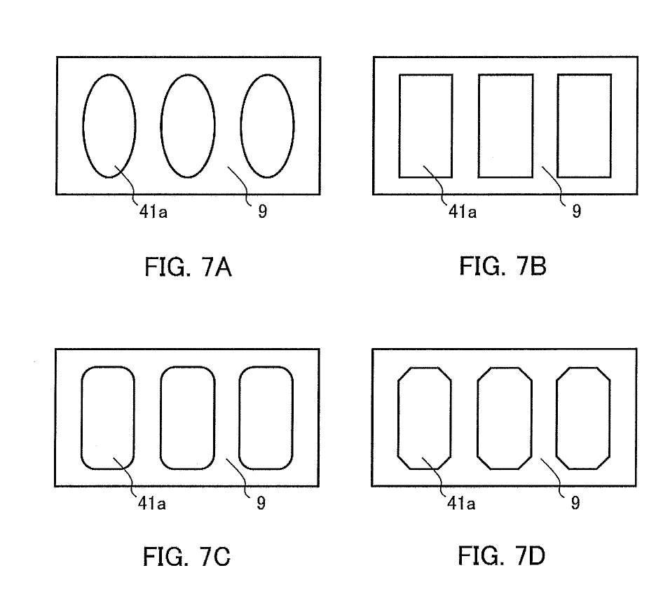

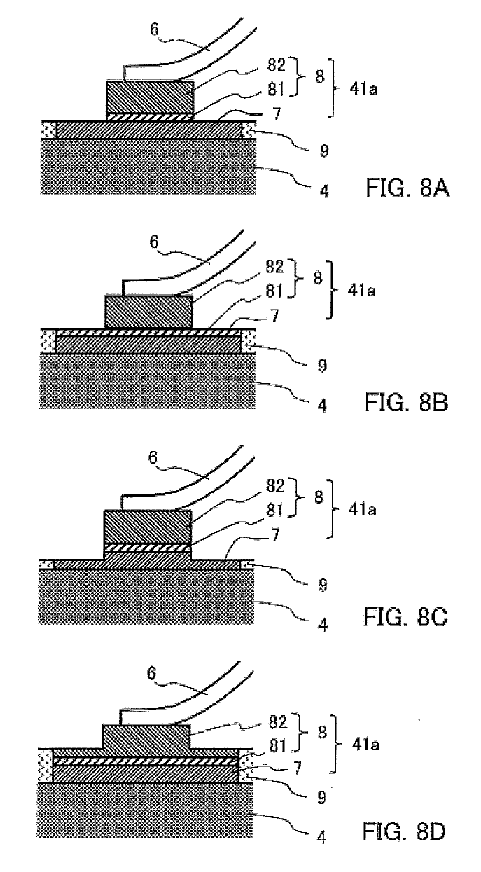

FIG. 5 is a perspective view showing a configuration of front-surface electrodes 41a of the power semiconductor element 4 in a power semiconductor device according to Embodiment 4 of the invention, and FIG. 6 is a cross-sectional view along B-B indicated by arrows in FIG. 5. Further, FIG. 7 and FIG. 8 are each a diagram showing other configurations of the front-surface electrodes 41a of the power semiconductor element 4 in the power semiconductor device according to Embodiment 4.

As shown in FIG. 5, the front-surface electrodes 41a of the power semiconductor element 4 are formed as ellipse shapes respectively provided for the plural wires 6 and each having an area of about 1.2 times the area of the bonding portion. On an entire region where the front-surface electrodes 41a are not present, an insulating layer 9 composed of polyimide is placed. In a power semiconductor element, in order to ensure an insulation property, polyimide is generally used around the circumference, etc. of the power semiconductor element; however, in Embodiment 4, it is formed as a film on the entire region where the front-surface electrodes 41a are not present. Further, as shown in FIG. 6 and like in Embodiment 1, in each of the front-surface electrodes 41a, the outermost surface is provided by the soft Cu layer 82 consisting mainly of Cu, formed by non-electrolytic plating and having a Vickers hardness of 70 to 150 Hv, and under that layer, the hard Cu layer 81 consisting mainly of Cu, formed by non-electrolytic plating and having a Vickers hardness of 200 to 350 Hv is placed. Further, under that layer, the Al layer 7 consisting mainly of Al is formed as a film. The wire 6 is bonded by wedge bonding to the Cu layer 82 formed to provide the outermost surface of the front-surface electrode 41a. The other configuration is also similar to in the power semiconductor device 100 of Embodiment 1, so that its description is omitted here.

When this configuration is applied, with respect to inconsistency between a material having a low linear expansion coefficient, such as the power semiconductor element 4 made of Si, the ceramic board 2 made of AlN, or the like, and the front-surface electrode 41a that is large in linear expansion coefficient, it becomes possible to disperse thermal stress. This makes it possible to suppress peeling, to thereby achieve improved reliability. Further, because the insulating layer 9 composed of polyimide functions as a mask, it is possible to forma pattern of the front-surface electrodes 41a, without adding a process, such as photoengraving or etching, for arranging that electrodes into a grid-like shape, so that the productivity is superior. Furthermore, the Al layer 7 is formed as a film over a whole surface under the Cu layer 8, it is prevented that a gap is developed between the Cu layer 8 and the insulating layer 9.

Note that, it suffices that each size of the front-surface electrodes 41a is 1 to 1.5 times the area of the bonding portion to the wire 6, and its shape is not limited to ellipse and may be rectangle as shown in FIG. 7 (see, FIG. 7B). At the time of that shape, in order to avoid stress concentration, its corners may be subjected to rounding processing (see, FIG. 7C), chamfering processing (see, FIG. 7D), or the like.

Further, as for the insulating layer 9, polyimide is used; however, this is not limitative. Its material just has to ensure an insulation property, and may be a nitride film, or the like. Further, such a configuration is applied in which the insulating layer 9 finally remains; however, it is allowable to use a method in which a resist is applied, followed by film formation of the front-surface electrode 41a, and the resist is removed after the film formation.

Further, in the front-surface electrode 41a, only a part of the layers that is placed in the surface side, may be formed so as to correspond to each wire 6. For example, in FIG. 8A, a case is shown where, on the Al layer 7, only the Cu layer 8 (Cu layer 81 and Cu layer 82) is formed by film formation so as to correspond to each wire 6, and in FIG. 8B, a case is shown where, on the Cu layer 81, only the Cu layer 82 is formed by film formation so as to correspond to each wire 6. Instead, after completion of film formations until the Cu layer 8, only a part of the layers in the front-surface electrode 41a, that is placed in the surface side, may be shaped so as to remain correspondingly to each wire 6. For example, in FIG. 8C, a case is shown where only the Cu layer 8 (Cu layer 81 and Cu layer 82) is shaped so as to remain correspondingly to each wire 6, and in FIG. 8D, a case is shown where only the Cu layer 82 is shaped so as to remain correspondingly to each wire 6. In these cases, the Al layer 7 is required to be 0.1 μm or more.

As described above, in accordance with the power semiconductor device according to Embodiment 4 of the invention, each of the front-surface electrodes 41a of the power semiconductor element 4, or a part of the layers in the front-surface electrode 41a, that is placed in the surface side, is formed so as to correspond to each of the plural wires 6, and the outermost-surface Cu layer 82 of the front-surface electrode 41a and each wire 6 corresponding thereto and made of Cu, are wire-bonded together. Thus, even when bonding using a Cu wire is applied to the power semiconductor element, it is possible not only to reduce damage to the power semiconductor element, but also to disperse thermal stress. Thus, it is possible to suppress peeling from occurring in the front-surface electrode, and thus wiring can be achieved with much superior reliability. Further, it is possible to improve the productivity.

### Embodiment 5

In Embodiment 4, the Cu layer 8 (Cu layer 81 and Cu layer 82) is formed in conformity with the shape of the Al layer 7, whereas in Embodiment 5, such a case will be described in which the Cu layer 8 (Cu layer 81 and Cu layer 82) is formed in an overhanging manner.

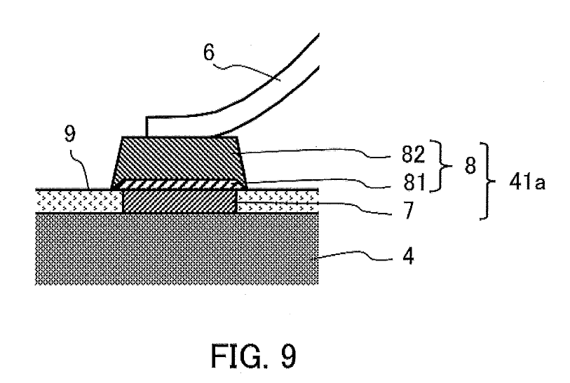

FIG. 9 is an enlarged cross-sectional view showing a configuration of a main part of the power semiconductor device according to Embodiment 5 of the invention. As shown in FIG. 9, in each of the front-surface electrodes 41a of the power semiconductor element 4, the Cu layer 8 (Cu layer 81 and Cu layer 82) is overhanging the insulating layer 9 in a state protruding on said insulating layer by about 1 to 10 μm so as to surround the Al layer 7. Like in Embodiment 4, in the front-surface electrode 41a, the outermost surface is provided by the soft Cu layer 82 consisting mainly of Cu, formed by non-electrolytic plating and having a Vickers hardness of 70 to 150 Hv, and under that layer, the hard Cu layer 81 consisting mainly of Cu, formed by non-electrolytic plating and having a Vickers hardness of 200 to 350 Hv is placed. Further, under that layer, the Al layer 7 consisting mainly of Al is formed as a film. Because the non-electrolytically plated layer 81 is plated on the non-electrolytically plated layer 82, the non-electrolytically plated layer 81 is overhanging the insulating layer 9 in a degree same as or more than that of the non-electrolytically plated layer 82. The other configuration is also similar to in the power semiconductor device of Embodiment 4, so that its description is omitted here.

As described above, in accordance with the power semiconductor device according to Embodiment 5 of the invention, in each of the front-surface electrodes 41a of the power semiconductor element 4, the Cu layer 8 (Cu layer 81 and Cu layer 82) is overhanging the insulating layer 9 in a state protruding on said insulating layer so as to surround the Al layer 7. Thus, even when bonding using a Cu wire is applied to the power semiconductor element, it is possible not only to reduce damage to the power semiconductor element and to disperse thermal stress, to thereby suppress peeling from occurring in the front-surface electrode, but also to prevent Al from galvanically corroding because Al is not exposed, so that wiring can be achieved with much superior reliability. Further, it is possible to improve the productivity.

In the power semiconductor devices according to the above-described respective embodiments, wire-bonding is done using the wire 6 made of Cu, so that the wiring is lower in electric resistance and larger in current capacity than that by the wire made of Al. Thus, as the power semiconductor element 4, a power semiconductor element formed of wide bandgap semiconductor, which is wider in bandgap than that made of Si, may be used. Examples of the wide bandgap semiconductor include, for example, silicon carbide (SiC), gallium nitride (GaN), diamond and the like.

The power semiconductor element formed of such wide bandgap semiconductor is high in withstand voltage and also high in allowable current density. In addition, it is also high in heat resistance. Thus, the cooling fin as a heat dissipation member can be downsized or can be replaced with an air-cooling type, so that it becomes possible to further downsize the power semiconductor device.

With the progress of downsizing of power semiconductor devices, more increased demand will emerge for ensuring heat dissipation capability and for long-term reliability against thermal stress. Even for such demand, the power semiconductor device of the invention exerts a superior effect.

It should be noted that unlimited combination of the respective embodiments, and appropriate modification or omission in the embodiments may be made in the present invention without departing from the scope of the invention.

### DESCRIPTION OF REFERENCE NUMERALS AND SIGNS

4: power semiconductor element, 6: wire, 7: Al layer, 8: Cu layer, 9: insulating layer, 41a: front-surface electrode, 81: Cu layer, 82: Cu layer, 83: metal layer, 100: power semiconductor device.

1.-22. (canceled)

23. A power semiconductor device, comprising:
a power semiconductor element;
a first electrode layer formed on the power semiconductor element;
a second electrode layer formed on the first electrode layer, said second electrode layer consisting mainly of Cu and having a hardness lower than that of the first electrode layer; and
a bonding wire consisting mainly of Cu and connected to the second electrode layer;
wherein the first electrode layer has a Vickers hardness of 200 to 350 Hv, and the second electrode layer has a Vickers hardness of 70 to 150 Hv.

24. The power semiconductor device according to claim 23, wherein the first electrode layer is a layer consisting mainly of Cu.

25. The power semiconductor device according to claim 23, wherein the first electrode layer comprises: an underlayer; and a layer consisting mainly of Cu and formed on the underlayer by non-electrolytic plating.

26. The power semiconductor device according to claim 25, wherein the second electrode layer is a layer consisting mainly of Cu and formed by non-electrolytic plating using the first electrode as a base.

27. The power semiconductor device according to claim 23, wherein the first electrode layer comprises an underlayer only, and the second electrode layer is a layer consisting mainly of Cu and formed by non-electrolytic plating using the first electrode layer as a base.

28. The power semiconductor device according to claim 23, wherein the first electrode layer has an average grain size of 1 μm or less.

29. The power semiconductor device according to claim 23, wherein the second electrode layer has an average grain size of 5 μm or more.

30. The power semiconductor device according to claim 23, wherein the first electrode layer has a film thickness of 5 to 20 μm.

31. The power semiconductor device according to claim 23, wherein the second electrode layer has a film thickness of 5 to 20 μm.

32. The power semiconductor device according to claim 25, wherein the underlayer of the first electrode layer has a film thickness of 0.1 to 5 μm.

33. The power semiconductor device according to claim 32, wherein the underlayer is formed of Al, Cu or Ni.

34. The power semiconductor device according to claim 23, wherein, between the first electrode layer and the second electrode layer, a metal film containing at least one of Au and Pd is formed with a film thickness of 0.1 μm or less.

35. The power semiconductor device according to claim 23, wherein plural bonding wires each being said bonding wire are provided, and plural second electrode layers each being said second electrode layer are formed respectively corresponding to the bonding wires, wherein at least the second electrode layers are each formed into an ellipse or rectangle shape.

36. The power semiconductor device according to claim 23, wherein plural bonding wires each being said bonding wire are provided, and plural second electrode layers each being said second electrode layer are formed respectively corresponding to the bonding wires, wherein an insulating layer is formed around a circumference of the first electrode layer and the second electrode layer.

37. The power semiconductor device according to claim 36, wherein the insulating layer is formed of a polyimide or nitride film.

38. The power semiconductor device according to claim 36, wherein the first electrode layer and the second electrode layer is overhanging the insulating layer around the circumference.

39. The power semiconductor device according to claim 38, wherein an area where the electrode is overhanging the insulating layer, has a width of 1 to 10 μm along the circumference.
